(19) United States
(12) Patent Application Publication
(10) Pub. No.: US 2008/0173795 A1
(43) Pub. Date: Jul. 24, 2008

(54) IMAGE SENSOR

(76) Inventor: Hwa-Young Kang, Suwon-si (KR)

Correspondence Address: CHA & REITER, LLC, 210 ROUTE 4 EAST STE 103, PARAMUS, NJ, 07652, US

(21) Appl. No.: 12/017,388

(22) Filed: Jan. 22, 2008

(30) Foreign Application Priority Data
Jan. 23, 2007 (KR) 7090-2007

(51) Int. Cl. H01L 27/00

(52) U.S. Cl. 250/208.1

(57) ABSTRACT

An image apparatus and method of fabrication that reduces the variation intensity different wavelengths, that can result in a reduce color variation of a recorded image as compared with the actual object. The apparatus particularly is effective to reduce variation in the case where light rays having a red wavelength. The image apparatus includes an sensor, a micro lens array preferably disposed on the sensor and having a plurality of micro lenses, and an infrared filter preferably deposited on an upper surface of the micro lens array, wherein the micro lenses have a predetermined curvature. The incident angle of the infrared filter can minimize the change of the wavelength band according to reducing the deviation in the incident angle of the rays of the photographed subject entering the infrared filter and that are sensed by the image sensor.

### CLAIM OF PRIORITY

This application claims the benefit of priority under 35 U.S.C.§119(a) from an application entitled “Image Sensor,” filed in the Korean Intellectual Property Office on November Jan. 23, 2007 and assigned Serial No, 2007-7090, the contents of which are hereby incorporated by reference in its entirety.

### BACKGROUND OF THE INVENTION

1. Field of the Invention

The present invention relates to an image sensor device. ore particularly, the present invention relates to an image sensor device including an infrared filter.

2. Description of the Related Art

An image sensor typically comprises a sensor in which a plurality of light detectors are integrated as respective pixels and includes an infrared filter. The image sensor is a type of a photoelectric conversion device that converting light rays of a subject to be photographed into electric signals; wherein the light rays are typically input from an exterior source, and the conversion is to electrically process an image of the photographed subject. The infrared filter used in a conventional image sensor has a function of enabling light rays of a visible wavelength band to be penetrated therethrough and also to intercept (filter) light rays in an infrared wavelength band.

Thus, in the conventional image sensor, the light rays of the photographed subject are capable of entering the infrared filter at an angle having an inclination of a predetermined degree respective to a certain normal line perpendicular to an incident surface of the infrared filter. In addition, a wavelength band of the infrared filter is shifted according to the incident angle of the rays.

FIG. 1 is a graph showing the measured change of a wavelength band according to incident angles of light rays entering the infrared filter, and the transmittance level shows a penetration characteristic of an infrared filter having a wavelength band of about 350 nm˜700 nm. Still referring to FIG. 1, when an incident angle of the rays entering the infrared filter is 0 degrees (in a case that the incident angle is paralleled with a normal line), it is easily understood that the wavelength band of the infrared filter does not change.

Meanwhile, when the incident angle with respect to a normal line becomes larger, it is understood that the wavelength band of the infrared filter is shifted toward a short wavelength band.

Referring to FIG. 1, at point 102, shown by the dashed line curve, when the incident angle of the rays is 30 degrees, a cut-off of the upper end wavelength is 641 nm, and at point 101, shown by the solid line curve, when the incident angle of the rays is 0 degrees, the cut-off wavelength is 675 nm. The bandwidth is 274 nm when the cut-off wavelength is 675 nm. As a result, it is understood that the wavelength band is changed as much as 33.5 nm.

Still referring to FIG. 1, the cut-off wavelength refers to a wavelength having a transmittance of 50% or a reflectance of 50%, which corresponds to a boundary in which the characteristic of the infrared filter changes. As can be seen in FIG. 1, the cut-off wavelength refers to a wavelength having a transmittance of 50%, which corresponds to a boundary in which the transmittance of a wavelength band is changed from 90% to 0%.

However, when an image is implemented from the light rays of the photographed subject, the change of the cut-off wavelength in the infrared light wavelength band can cause a color variation of the implemented image. Particularly, in the case where light rays having a red wavelength can cause a significant color variation compared with rays having other types of wavelengths.

FIGS. 2A to 2C are graphs showing measured light intensity according to positions of respective images implemented by an image displayer (positions of pixels in which the images are implemented) when three primary colors of red, green, and blue (the group of colors often referred to as “RGB”) are input to the image sensor, respectively. In other words, FIG. 2A shows the light intensity of visible light that is red, FIG. 2B shows the light intensity of green light, and FIG. 2C shows the light intensity of blue light.

FIGS. 2A to 2C are graphs showing light intensity measured many times by using a plurality of light sources, in which respective kinds of rays have corresponding light sources different from each other, respectively. The x axis refers to a pixel position according to a profile in a diagonal direction shown in FIG. 2D. Also, each y axis of FIGS. 2A to 2C refers to a signal level according to each x axis. The measurement of the light intensity shown in FIGS. 2A to 2C is based on an 8 bit scale.

According to the graphs of FIGS. 2A to 2C, the deviation between the light intensities of the corresponding wavelengths according to the positions of the image pixels can be understood. For example, FIG. 2A is the graph showing light intensity when rays of a red wavelength are measured, FIG. 2B is the graph showing light intensity when rays of a green wavelength are measured, and FIG. 2C is the graph showing light intensity when rays of a blue wavelength are measured.

Referring to FIGS. 2A to 2B, it is understood that the deviation is largest in the center part of a curved graph showing the red wavelength (FIG. 2A). Therefore, it is also understood that the change of the cut-off wavelength of the infrared filter may be a main reason for causing color variation while the image is implemented in the image sensor.

Accordingly, the change of the cut-off wavelength in the infrared light wavelength band can increase the fraction proportion of the image sensor, and there is a problem in that the controlling time increases according to the characteristic of the infrared filter when assembling the image sensor.

### SUMMARY OF THE INVENTION

Accordingly, the present invention has been made in part to solve at least some of the above-mentioned problems occurring in the prior art. The present invention provides an image sensor including a infrared filter that can minimizes the change of a cut-off wavelength according to incident angles of rays of a subject to be photographed.

In accordance with an exemplary aspect of the present invention, there is provided an image sensor device and method of fabrication including: a sensor, a micro lens array disposed on the image sensor and having a plurality of micro lenses; and an infrared filter deposited on an upper surface of the micro lens array, wherein the micro lenses have a predetermined curvature.

### BRIEF DESCRIPTION OF THE DRAWINGS

The above and other exemplary aspects, features and advantages of the present invention will be more apparent from the following detailed description taken in conjunction with the accompanying drawings, in which:

FIG. 1 is a graph showing the change of a wavelength band of light according to an incident angle of a ray entering an infrared filter;

FIGS. 2A to 2C are graphs showing measured light intensity according to positions of pixels when three primary colors of red, green, and blue are implemented, respectively, by an image display;

FIG. 2D is a view showing a screen of the image display used for measuring the light intensity shown in FIGS. 2A to 2C;

FIG. 3 is a sectional view showing an image sensor shown in FIG. 3 according to an exemplary embodiment of the present invention; and

FIG. 4 is an enlarged view showing a part of the image sensor shown in FIG. 3.

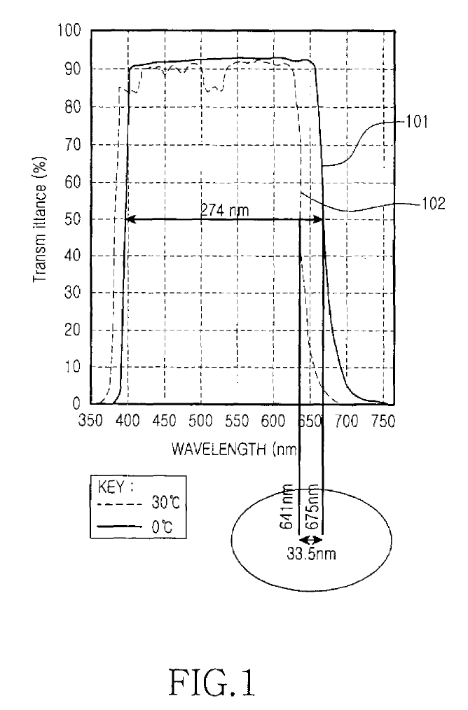

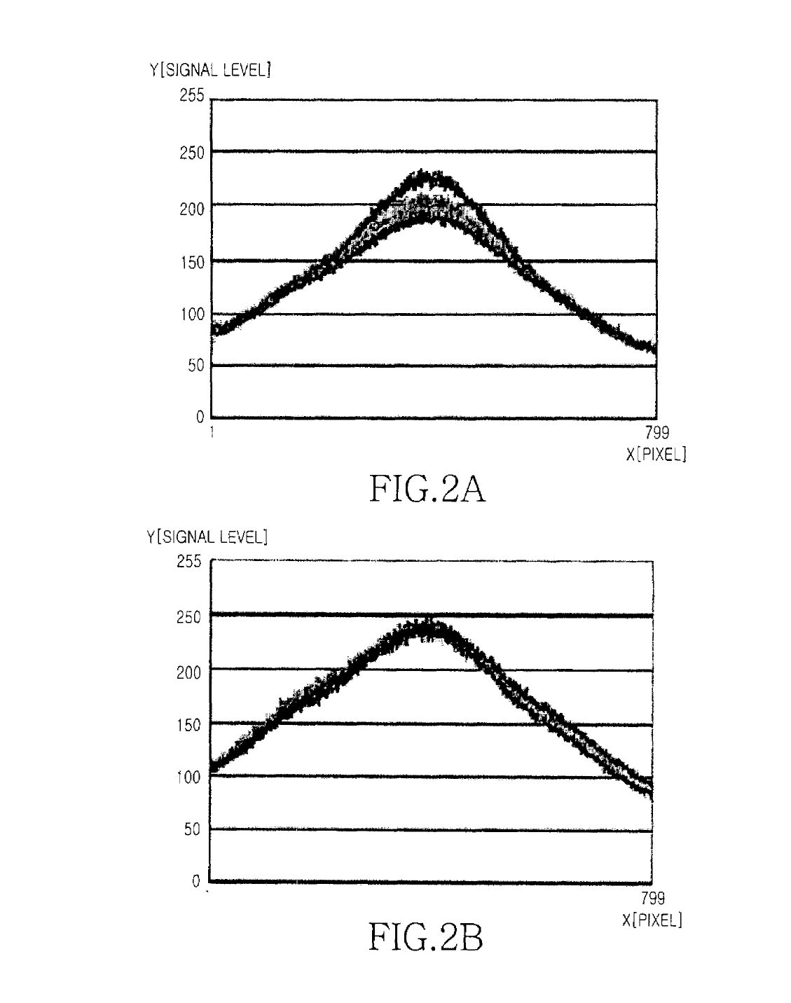

### DETAILED DESCRIPTION OF THE INVENTION

Hereinafter, exemplary embodiments of the present invention will be described with reference to the accompanying drawings. For the purposes of clarity and simplicity, a detailed description of known functions and configurations incorporated herein will be omitted as it may make the subject matter of the present invention rather unclear.

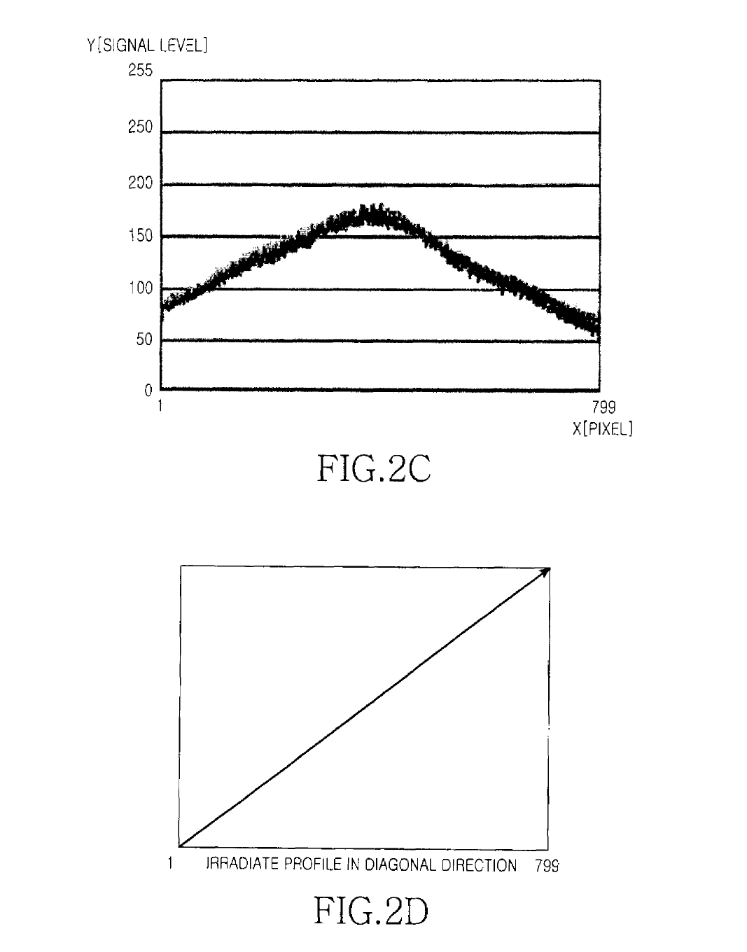

FIG. 3 is a sectional view showing an image sensor device according to an exemplary embodiment of the present invention. Referring to FIG. 3, the image sensor 200 according to the present invention includes a sensor 210 having a plurality of pixels integrated therein, a micro lens array 220 disposed on an upper surface of the sensor 210, and an infrared filter 230 deposited on an upper surface of the micro lens array 220. Arrows illustrated in FIG. 3 refer to rays entering the image sensor.

The micro lens array 220 typically includes a plurality of micro lenses 221 having a predetermined curvature.

Still referring to FIG. 3, the sensor 210 includes a plurality of pixels therein, respective pixels refer to a minimum point implementing an image in a second dimension. Particularly, after penetrating through the infrared filter 230, light rays of a photographed subject can enter respective pixels via the micro lens 221, and after entering respective pixels, the rays of the photographed subject can be implemented as an image via the image sensor 200. The sensor 210 may comprise, for example, a charge-coupled device (CCD) sensor or a CMOS sensor but are not limited to those types of sensors.

The infrared filter 230 is typically formed on the upper surface of the micro lens array 22 so that a deviation between incident angles of the entering rays can be minimized due to a curvature of the micro lens 221. However, a person of ordinary skill in the art understands and appreciates that while it is preferable that the infrared filter is formed on the upper surface of the micro lens array and permits easier fabrication, it is within the spirit of the invention and the scope of the appended claims that the lower (i.e. inner surface could have the infrared filter formed thereon instead of or in addition thereto).

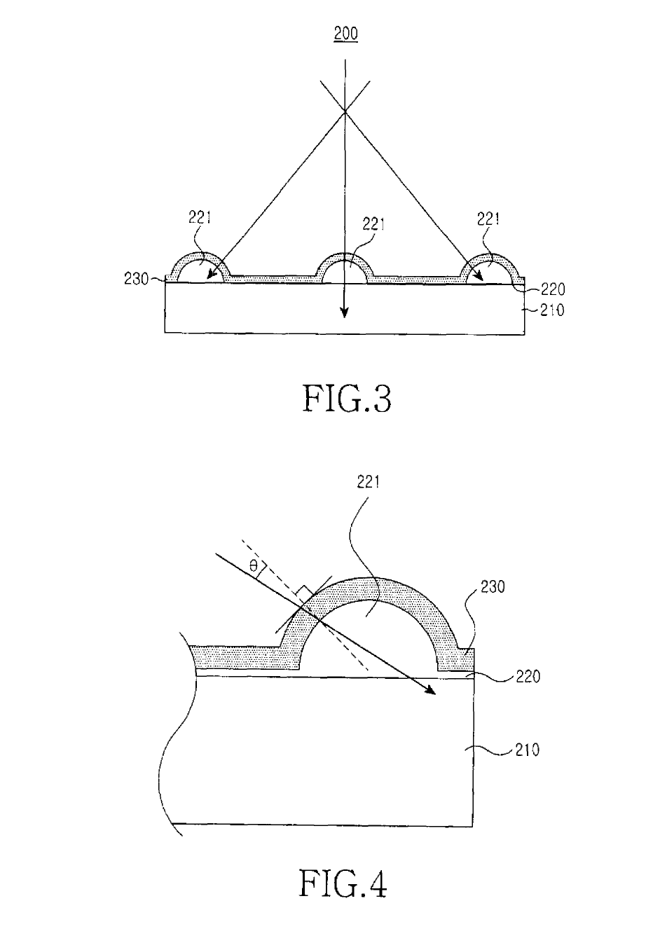

FIG. 4 is a magnified view showing a part of the exemplary image sensor 200 shown in FIG. 3. T he dotted line shown in FIG. 4 refers to a certain normal line perpendicular to an incident surface of the infrared filter 230 in which the light rays enter, and an the solid line arrow identifies the ray entering the infrared filter 230. Referring to FIG. 4, in the infrared filter 230 according to the present invention, the incident surface, in which the ray enters, is formed in a curved shape according to the curvature or the micro lens 221, thereby minimizing the difference between the incident angles of rays entering the infrared filter 230 formed on the micro lens 221 with a predetermined angle with respective to the normal line.

Therefore, while the infrared filter 230 according to the present invention may have a difference between the predetermined angle and the incident angles of the entering rays, the difference is smaller than that of a conventional flat-type infrared filter. Also, the infrared filter 230 can minimize the change of the cut-off wavelength depending on the difference between incident angles of rays to be implemented as images in the center of and a lateral part of the image sensor 200, respectively. It is preferable that the infrared filter as a curvature that substantially corresponds to a predetermined curvature of the micro lenses.

The incident angle reveals the slanting degree of a ray based on a certain normal line perpendicular to a surface (or a point) which the ray enters. Therefore, according to the present invention, the infrared filter 230 is typically formed on the upper surface of the micro lens 221 having a same or similar curvature, thereby minimizing the difference between the incident angles of the rays entering the micro lens 221.

The present invention also contemplates a method of forming an image sensor device, which can be made by the following exemplary steps: (a) providing a sensor having a plurality of pixels integrated therein; (b) arranging a micro lens array on the sensor, said micro lens array comprising a plurality of micro lenses; and (c) depositing an infrared filter on an upper surface of the micro lens array.

Therefore, according to the present invention, the change of the wavelength band, depending on the incident angles of the rays entering the infrared filter 230, can be minimized, and the deviation of the cut-off wavelength can be also minimized.

The image sensor according to the present invention includes the infrared filter deposited on the micro lens array having a plurality of micro lenses formed therein, thereby minimizing the change of the wavelength band according to the incident angle of the rays of the photographed subject entering the infrared filter.

Particularly, the infrared filter deposited on the upper surface of the micro lens can minimize the difference in incident angles of the entering rays. The deviation between incident angles can be minimized. Therefore, there is an advantage in that the color variation can be minimized when the images are implemented in the image sensor.

While the invention has been shown and described with reference to certain exemplary embodiments thereof, it will be understood by those skilled in the art that various changes in form and details may be made therein without departing from the spirit the invention and the scope of the appended claims. For example the term light rays (rays) and may include exterior light other than light in the visible spectrum, for example when sunlight is illuminating an object being photographed, or it can be light from a camera flash. etc. The infrared filter is deposited on the upper surface of the micro lens array, and this can be a coating, or it is within the spirit and scope of the invention that it could be a separate structure arranged on the micro lens array. Furthermore, a substantial entirety of the micro lens array can be have an infrared filter coated/deposited thereon, or only a portion, for example, just the micro lenses themselves, or only some of the micro lenses. Also, the predetermined curvature of the micro lenses may not be uniform throughout the micro lens array, and while the infrared filter preferably has a curvature that substantially corresponds to the predetermined curvature of the micro lenses, there can be variations, and it is within the spirit and scope of the invention that not all of the micro lenses must have the infrared filter deposited thereon, etc.

What is claimed is:

1. An image sensor device comprising:
a sensor having a plurality of pixels integrated therein;
a micro lens array disposed on the sensor, said micro lens array comprising a plurality of micro lenses; and
an infrared filter deposited on an upper surface of the micro lens array.

2. The image sensor device according to claim 1, wherein the infrared filter is deposited on each of the plurality of micro lenses of the micro lens array.

3. The image sensor device according to claim 1, wherein the infrared filter is deposited on some of the plurality of micro lenses of the micro lens array.

4. The image sensor device according to claim 1, wherein the micro lenses have a predetermined curvature.

5. The image sensor device according claim 1, wherein the sensor includes a CCD or CMOS sensor.

6. An image sensor device comprising:
a sensor having a plurality of pixels integrated therein;
a micro lens array disposed on the sensor, said micro lens array comprising a plurality of micro lenses; and
an infrared filter arranged on an upper surface of the micro lens array.

7. The image sensor device according to claim 6, wherein the micro lenses have a predetermined curvature.

8. The image sensor device according to claim 7, wherein the infrared filter has a predetermined curvature that substantially corresponds to the predetermined curvature of the micro lenses.

9. An image sensor device comprising.
a sensor having a plurality of pixels integrated therein;
a micro lens array disposed on the sensor, said micro lens array comprising a plurality of micro lenses; and
an infrared filter arranged on a surface of some of the plurality of micro lenses.

10. The image sensor device according to claim 9, wherein the infrared filter is arranged on all of the plurality of micro lenses.

11. The image sensor device according to claim 9, wherein the infrared filter is arranged on a lower surface of the micro lenses.

12. The image sensor according to claim 9, wherein the micro lenses have a predetermined curvature.

13. The image sensor according to claim 12, wherein the infrared filter has a curvature that substantially corresponds to the predetermined curvature of the micro lenses.
